(19) United States
(12) Patent Application Publication
(10) Pub. No.: US 2025/0201747 A1
(43) Pub. Date: Jun. 19, 2025

(54) ELECTRONIC DEVICE AND MANUFACTURING METHOD THEREOF

(71) Applicant: Taiwan Semiconductor Manufacturing Company, Ltd., Hsinchu (TW)

(72) Inventors: Tzu-Shiun Sheu, Hsinchu (TW); Chang-Hsuan Lee, Hsinchu County (TW); Yung-Ping Chiang, Hsinchu County (TW)

(73) Assignee: Taiwan Semiconductor Manufacturing Company, Ltd., Hsinchu (TW)

(21) Appl. No.: 18/403,747

(22) Filed: Jan. 4, 2024

Related U.S. Application Data
(60) Provisional application No. 63/609,873, filed on Dec. 14, 2023.

(51) Int. Cl. H01L 23/00; H01L 25/18; H10B 80/00

(52) U.S. Cl. CPC H01L 24/13; H01L 24/03; H01L 24/05; H01L 24/10; H01L 24/11; H01L 24/16; H01L 24/32; H01L 24/73; H01L 24/81; H01L 25/18; H01L 2224/03912; H01L 2224/05558; H01L 2224/05567; H01L 2224/05655; H01L 2224/05657; H01L 2224/05684; H01L 2224/05686; H01L 2224/10145; H01L 2224/11827; H01L 2224/13083; H01L 2224/13111; H01L 2224/13144; H01L 2224/13155; H01L 2224/13565; H01L 2224/1357; H01L 2224/13686; H01L 2224/16145; H01L 2224/32145; H01L 2224/73204; H01L 2224/81007; H01L 2224/81815; H01L 2924/04541; H01L 2924/04642; H01L 2924/0469; H01L 2924/04941; H01L 2924/04953; H01L 2924/05042; H01L 2924/0509; H01L 2924/0544; H01L 2924/059; H10B 80/00

(57) ABSTRACT

An electronic device including a substrate, a conductive connector, a conductive bonding material, and a spacer layer is provided. The conductive connector is disposed on the substrate. The conductive bonding material is disposed on the conductive connector. The spacer layer laterally covers the conductive connector.

### CROSS-REFERENCE TO RELATED APPLICATION

This application claims the priority benefit of U.S. provisional application Ser. No. 63/609,873, filed on Dec. 14, 2023. The entirety of the above-mentioned patent application is hereby incorporated by reference herein and made a part of this specification.

### BACKGROUND

A corresponding bonding process for connecting a terminal of a chip is often included during the manufacture of an electronic apparatus. As chip manufacturing technology improves, the number and/or density of terminals on a chip may increase. Therefore, how to improve the quality or yield of the electronic apparatus has become a research topic.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1E illustrate various cross-sectional views of some embodiments of a method of forming an electronic device.

FIGS. 2A-2B illustrate various cross-sectional views of some embodiments of a method of forming an electronic device.

FIGS. 3A-3E illustrate various cross-sectional views of some embodiments of a method of forming an electronic device.

FIGS. 4A-4B illustrate various cross-sectional views of some embodiments of a method of forming an electronic device.

FIG. 5 illustrates an exemplary cross-sectional view of an electronic device.

FIG. 6 illustrates a flow diagram of some embodiments of a method of forming an electronic device.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

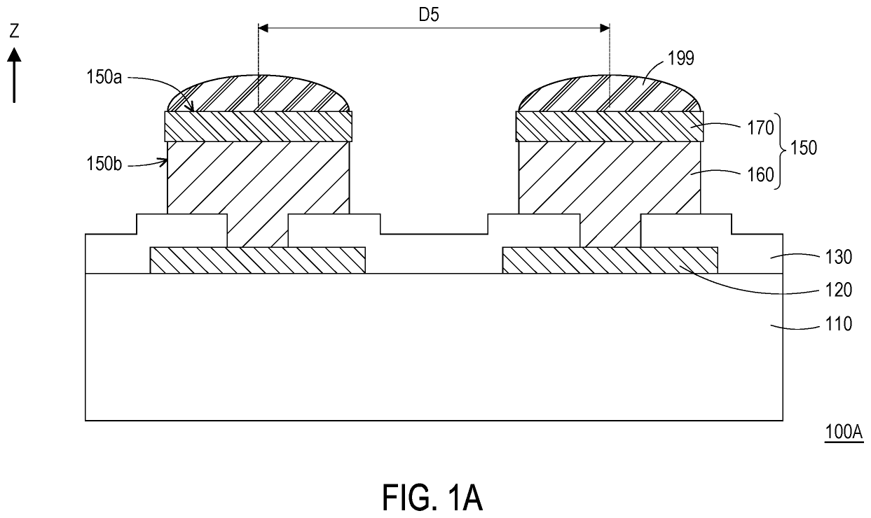

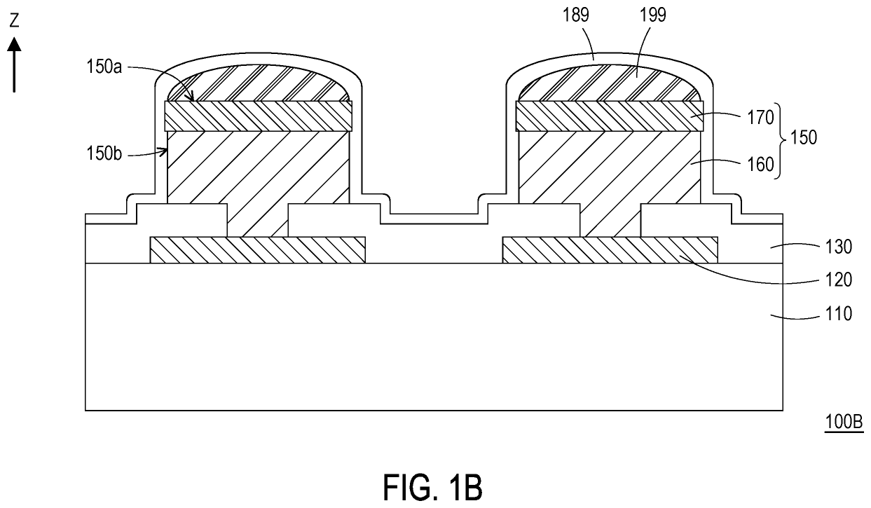

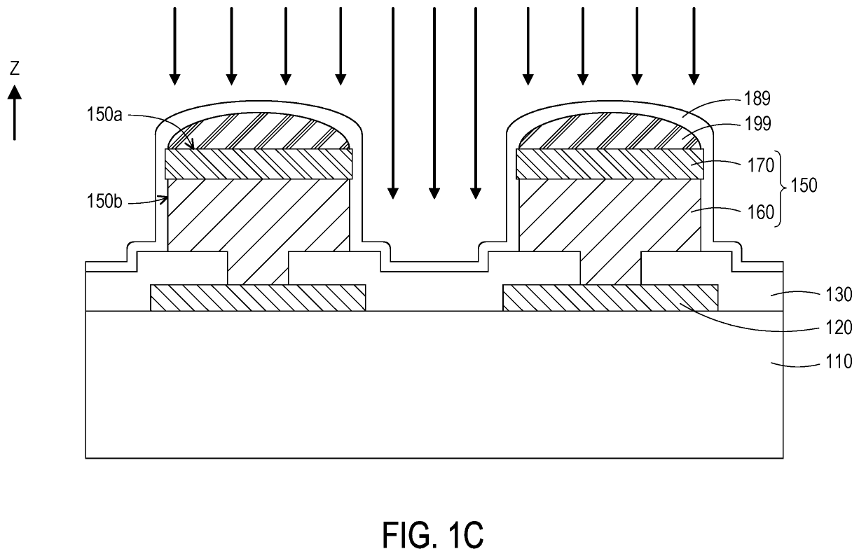

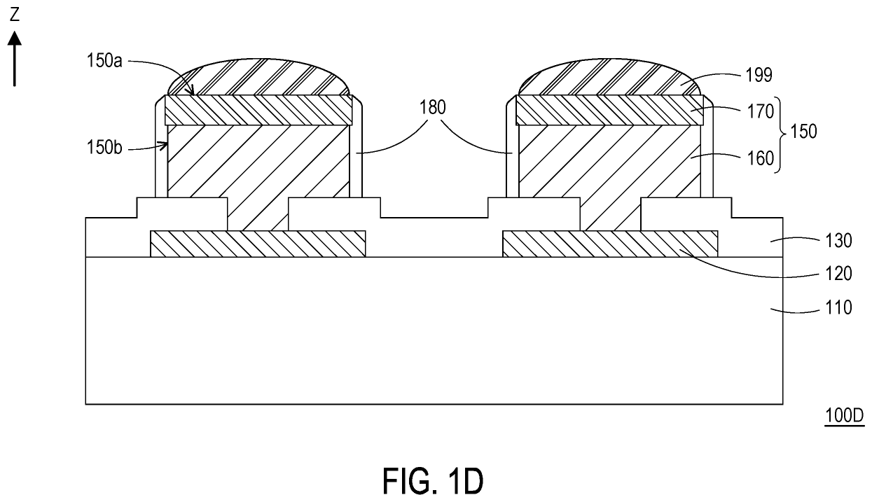

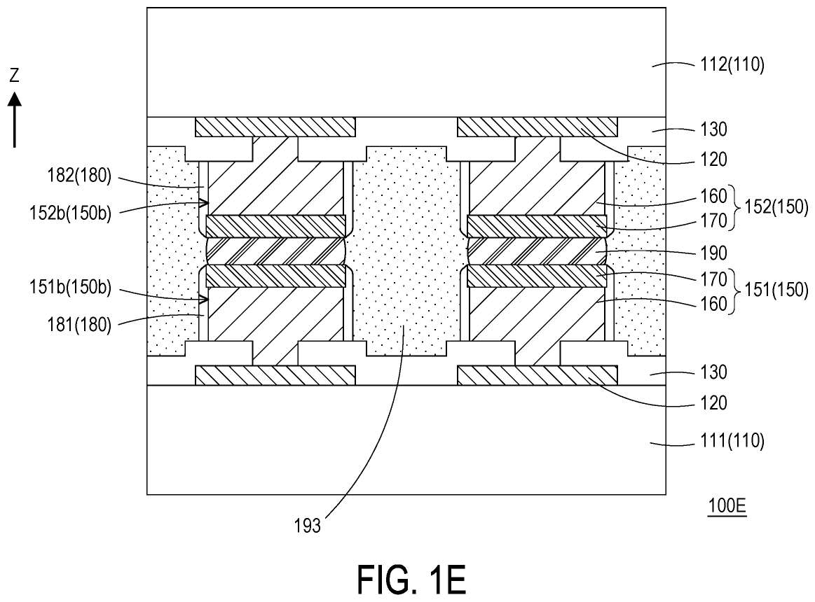

FIGS. 1A-1E illustrate various cross-sectional views of some embodiments of a method of forming an electronic device.

As shown in cross-sectional view of FIG. 1A, a structure 100A including a substrate 110 and conductive connectors 150 disposed on the substrate 110 is provided. The structure 100A may be referred as an electronic device.

The substrate 110 may include a semiconductor substrate (e.g., a silicon (Si) substrate or a semiconductor wafer), a printed circuit board (e.g., an FR-4 printed circuit board), or a glass substrate, but the disclosure is not limited thereto. A structure including a semiconductor substrate may be referred as a semiconductor structure. Take the semiconductor wafer as an example, the substrate 110 includes a crystalline silicon wafer. The substrate 110 may include various doped regions depending on design requirements (e.g., p-type substrate or n-type substrate). In some embodiments, the doped regions may be doped with p-type or n-type dopants. The doped regions may be doped with p-type dopants, such as boron or BF2; n-type dopants, such as phosphorus or arsenic; and/or combinations thereof. The doped regions may be configured for n-type Fin-type Field Effect Transistors (FinFETs) and/or p-type FinFETs. In some alternative embodiments, the substrate 110 is made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. The substrate 110 may further include interconnect structure formed over and electrically connected to the various doped regions. The interconnect structure may include a circuitry fabricated by back end of line (BEOL) processes.

In an embodiment, the conductive connectors 150 include conductive pillars, conductive bumps, conductive pastes, conductive layers, stacks or a combination thereof, but the disclosure is not limited thereto.

For example, each of the conductive connectors 150 includes a first conductive portion 160 and a second conductive portion 170 disposed on the first conductive portion 160. The first conductive portion 160 of each conductive connectors 150 may include a conductive pillar or a conductive bump. The second conductive portion 170 of each conductive connectors 150 may include a conductive layer. In some embodiments, the first conductive portion 160 of each conductive connectors 150 includes a copper (Cu) pillar or a copper bump, and the second conductive portion 170 of each conductive connectors 150 includes a nickel (Ni) layer or a gold (Au) layer, wherein the gold layer may be an electroless nickel immersion gold (ENIG) layer.

In an embodiment, in a cross-sectional view (e.g., the view as shown in FIG. 1A), the width of the second conductive portions 170 is greater than the width of the first conductive portions 160.

In an embodiment, a distance D5 (i.e., the arrangement pitch) between two adjacent conductive connectors 150 is less than 50 micrometers (μm). In yet other embodiments, the distance D5 is less than or approximately equal to 20 μm. In some other embodiments, the distance D5 is less than or approximately equal to 15 μm. In some alternative embodiments, the distance D5 is less than or approximately equal to 12 μm.

In an embodiment, the electronic device 100A further includes contact pads 120. The contact pads 120 may be Cu pads or aluminum (Al) pads. The conductive connectors 150 may be disposed on and electrically connected to the contact pads 120 correspondingly. Devices (e.g., transistors) fabricated by front end of line (FEOL) processes and/or a circuitry fabricated by back end of line (BEOL) processes may be electrically connected to the corresponding conductive connectors 150 by the contact pads 120 correspondingly.

In an embodiment, an insulating layer 130 is disposed on the substrate 110 and covers the contact pads 120. In an embodiment, the insulating layer 130 may be referred as a passivation layer. The conductive connectors 150 may penetrate through the insulating layer 130 to electrically connect with the contact pads 120.

Conductive bonding material layers 199 are formed on the conductive connectors 150. For example, the conductive bonding material layers 199 are formed on the top surfaces 150a of the conductive connectors 150. In an embodiment, the conductive bonding material layers 199 do not cover the side surfaces 150b of the conductive connectors 150. In other words, the conductive bonding material layers 199 exclusively distributed on the top surfaces of the conductive connectors 150, and the conductive bonding material layers 199 are not in contact with the side surfaces 150b of the conductive connectors 150.

To facilitate the subsequently performed reflow process (illustrated FIG. 1E), the melting point of the conductive bonding material layers 199 is lower than the melting point of conductive connectors 150. In an embodiment, the conductive bonding material layers 199 include tin (Sn). The conductive bonding material layers 199 may be referred as a solder material.

In an embodiment, a formation method of the conductive bonding material layers 199 include a deposition process (e.g., a plating process) followed by a heating or thermal process. As such, the conductive bonding material layers 199 may have an arc-shaped outer surface due to the cohesion property for molten metal in the conductive bonding material layers 199.

In an embodiment, the conductive bonding material layers 199 do not completely cover the top surfaces 150a of the conductive connectors 150. That is, portions of the top surfaces 150a of the conductive connectors 150 may be exposed. The portions (e.g., ring-shaped portions) of top surfaces 150a which are proximity to the side surfaces 150b may be exposed.

As shown in cross-sectional view of FIG. 1B, a structure 100B including a spacer material 189 is provided. The spacer material 189 is formed over the insulating layer 130 to cover the conductive connectors 150 and the conductive bonding material layers 199.

The spacer material 189 may be formed by a deposition process (e.g., chemical vapor deposition (CVD), atomic layer deposition (ALD), or the like), but the disclosure is not limited thereto. The spacer material 189 may at least cover exposed surfaces of the conductive connectors 150 as shown in FIG. 1A. For example, the spacer material 189 covers the side surfaces 150b of the conductive connectors 150. Additionally, the deposition direction (e.g., the thickness direction Z) of the deposition process for forming the spacer material 189 is substantially perpendicular to the top surfaces of the conductive connectors 150.

As illustrated in FIG. 1B, the spacer material 189 may further covers the top surfaces of the conductive bonding material layers 199. For example, the spacer material 189 covers the arc-shaped outer surfaces of the conductive bonding material layers 199.

As shown in FIG. 1B, the spacer material 189 may conformally cover the upper surface of the structure as shown in FIG. 1A. In an embodiment, the portions of the spacer material 189 which cover the side surfaces of the conductive connectors 150 have a larger or largest dimension in the thickness direction Z of the structure 100B.

In an embodiment, a material of the spacer material 189 is an inorganic material. Compared with an organic material, the inorganic material for forming the spacer material 189 may have better bonding ability with the substrate 110 or an inorganic layer disposed on the substrate 110, and the inorganic material for forming the spacer material 189 may be more suitable for a subsequent process. The material of the spacer material 189 may include silicon oxide (SiO), silicon nitride (SIN), silicon carbide (SiC), silicon oxynitride (SiON), silicon carbide nitride (SiCN), silicon oxycarbide (SiOC), silicon oxycarbonitride (SiOCN), and/or combinations thereof.

Referring to FIG. 1C and FIG. 1D, a removal process is performed. The removal process could be performed on the structure as shown in FIG. 1B. The removal process may be a mask-less or mask-free process. In other words, the removal process may be performed without using a mask. The removal process may be or include an anisotropic dry etching process performed without using a mask. The anisotropic dry etching process may be or include a reactive ion etching (RIE) process, but the disclosure is not limited thereto. In an embodiment, since the removal process includes an anisotropic dry etching process, the portions of the spacer material 189 having a larger or largest dimension along the thickness direction Z of the structure are not entirely removed.

After performing the above-mentioned removal process, portions of the spacer material 189 are removed such that spacer layers 180 are formed on sidewalls of the conductive connectors 150.

As shown in cross-sectional view of FIG. 1D, a structure 100D including spacer layers 180 is formed. The structure 100D as shown in FIG. 1D may be referred as an electronic device.

The structure 100D may include a substrate 110, conductive connectors 150, a conductive bonding material layers 199, and spacer layers 180. The conductive connectors 150 are disposed on the substrate 110. The conductive bonding material layers 199 is disposed on the conductive connectors 150. The spacer layers 180 laterally cover the conductive connectors 150. The contact pads 120 and the insulating layer 130 may be structurally considered as a part of the substrate.

The structure 100D may be referred as including a cylindrical connector having a solid cylindrical conductive core (e.g., the conductive connector 150) and an insulating layer sheath (e.g., spacer layer 180) laterally surrounding the conductive core. In an embodiment, the conductive bonding material layers 199 are not in contact with the side surfaces 150b of the conductive connectors 150 essentially.

In an embodiment, a maximum dimension of the spacer layers 180 is along a thickness direction Z of the structure 100D. The film thickness of portions of the spacer layers 180 corresponding to the first conductive portions 160 are larger than the film thickness of other portions of the spacer layers 180 corresponding to the second conductive portions 170.

In an embodiment, the portions (e.g., ring-shaped portions) of top surfaces 150a which are proximity to the side surfaces 150b are exposed. That is, the conductive bonding material layers 199 and the spacer layers 180 do not completely cover the top surfaces 150a of the conductive connectors 150.

As shown in cross-sectional view of FIG. 1E, a structure 100E including a conductive bonding layer 190 is formed. The structure 100E as shown in FIG. 1E may be referred as a bonded electronic device (e.g., an example type of an electronic device). For example, the structure 100D as shown in FIG. 1D is bonded to another structure which is the same or similar to the structure 100D by a corresponding bonding process, and the conductive bonding material layers 199 (as shown in FIG. 1D) may form conductive bonding layers 190 through the aforementioned bonding process. The conductive bonding layers 190 may be referred as a type of conductive bonding material.

In an embodiment, the aforementioned bonding process includes a heating or thermal process. For example, the aforementioned bonding process may include a reflow process, but the disclosure is not limited thereto. The melting point of the conductive bonding material layers 199 is lower than the melting point and/or the dissociation temperature of the spacer layers 180.

The cohesion of the molten conductive bonding material layers 199 may be greater than the adhesion between the molten conductive bonding material layers 199 and the spacer layers 180; and/or, the adhesion between the molten conductive bonding material layers 199 and the conductive connectors 150 may be greater than the adhesion between the molten conductive bonding material layers 199 and the spacer layers 180. Additionally, the spacer layers 180 laterally cover the conductive connectors 150. As such, the possibility of molten conductive bonding material layers 199 overflowing outside the top surfaces 150a of the conductive connectors 150 during the aforementioned bonding process may be reduced. That is, the possibility of electrical short between adjacent conductive connectors 150 may be reduced.

The structure (may be referred as a bonded electronic device) 100E may include a first substrate 111, first conductive connectors 151, first spacer layers 181, a second substrate 112, second conductive connectors 152, second spacer layers 182, and conductive bonding layers 190. The first conductive connectors 151 are disposed on (above in the drawing) the first substrate 111. The first spacer layers 181 laterally cover the first conductive connectors 151. The second conductive connectors 152 are disposed on (below in the drawing) the second substrate 112. The second spacer layers 182 laterally cover the second conductive connectors 152. The conductive bonding layers 190 are disposed between the first conductive connectors 151 and the second conductive connectors 152 and are electrically connected thereof.

In an embodiment, the material, formation methods and/or structural features of the first spacer layers 181 and the second spacer layers 182 are the same or similar to each other. The first spacer layers 181 and the second spacer layers 182 are physically separated from each other.

In an embodiment, the conductive bonding layers 190 are not in contact with the side surfaces 151b of the first conductive connectors 151 and the side surfaces 152b of the second conductive connectors 152 essentially.

In an embodiment, the bonded electronic device 100E further include a filling material 193. The filling material 193 is formed between the first substrate 111 and the second substrate 112. The filling material 193 includes an organic material. The filling material 193 includes a capillary underfill (CUF) material or a molding compound (e.g., epoxy).

In an embodiment, the filling material 193 is in contact with portions of top surfaces 150a of the conductive connectors 150. For example, the filling material 193 is in contact with the portions (e.g., ring-shaped portions) of top surfaces 150a which are proximity to the side surfaces 150b.

In an embodiment, the first spacer layers 181 are disposed between the first conductive connectors 151 and the filling material 193; and/or, the second spacer layers 182 are disposed between the second conductive connectors 152 and the filling material 193. The filling material 193 is not in contact with the side surfaces 151b of the first conductive connectors 151 and the side surfaces 152b of the second conductive connectors 152 essentially.

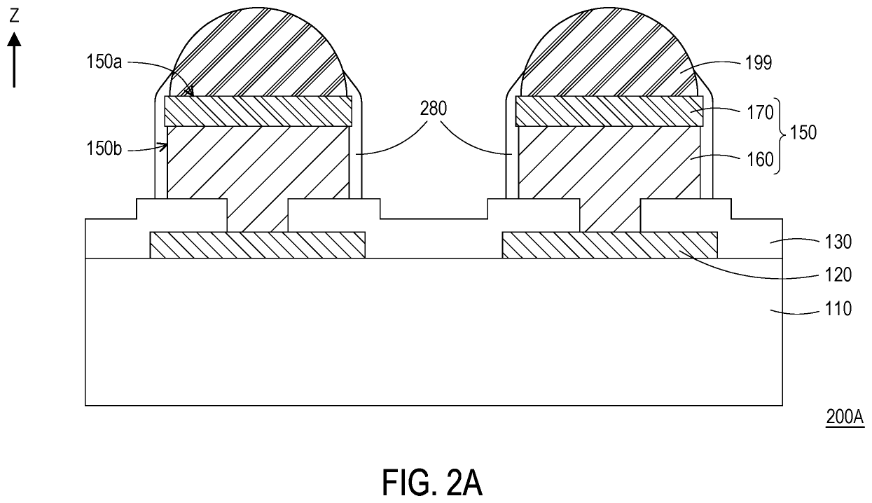

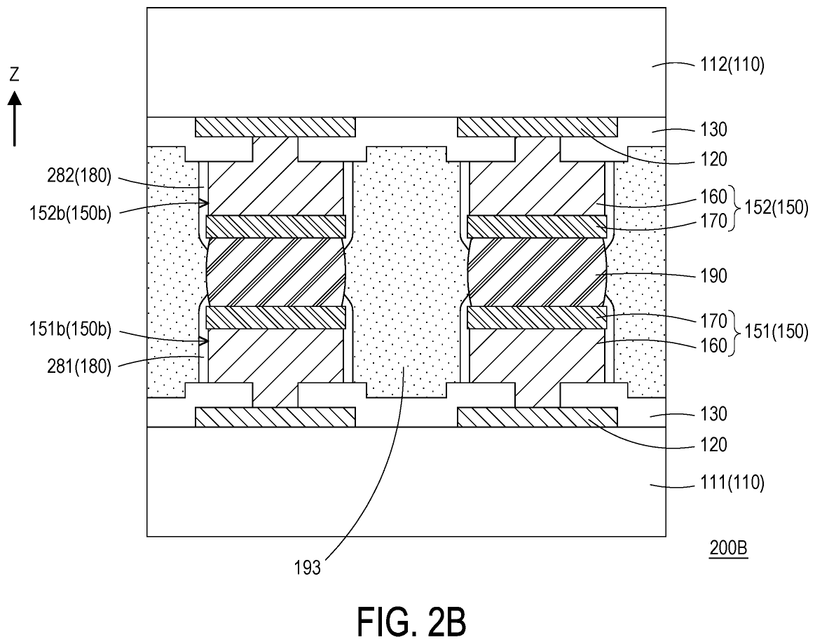

FIGS. 2A-2B illustrate various cross-sectional views of some embodiments of a method of forming an electronic device. In some embodiments, FIGS. 2A-2B may illustrate an exemplary method of forming an electronic device after the structure as shown in FIG. 1B.

As shown in cross-sectional view of FIG. 2A, a structure 200A including spacer layers 280 is formed. The structure 200A as shown in FIG. 2A may be referred as an electronic device. The spacer layers 280 may be formed by a removal process the same or similar to the process as described or shown in FIG. 1C.

The structure 200A may include the substrate 110, conductive connectors 150, a conductive bonding material layers 199, and spacer layers 280. The spacer layers 280 laterally cover the conductive connectors 150, and further cover portions of the conductive bonding material layers 199.

The structure 200A may be referred as including a cylindrical connector having a solid cylindrical conductive core (e.g., the conductive connector 150) and an insulating layer sheath (e.g., spacer layer 280) laterally surrounding the conductive core.

In an embodiment, a maximum dimension of the spacer layers 280 is along a thickness direction Z of the structure 200A. The film thickness of portions of the spacer layers 280 corresponding to the first conductive portions 160 are larger than the film thickness of other portions of the spacer layers 280 corresponding to the second conductive portions 170.

As shown in cross-sectional view of FIG. 2B, a structure 200B including a conductive bonding layer 190 is formed. The structure 200B as shown in FIG. 2B may be referred as a bonded electronic device (e.g., an example type of an electronic device). For example, the structure 200A as shown in FIG. 2A is bonded to another structure which is the same or similar to the structure 200A by a corresponding bonding process.

The structure (may be referred as a bonded electronic device) 200B may include a first substrate 111, first conductive connectors 151, first spacer layers 281, a second substrate 112, second conductive connectors 152, second spacer layers 282, and conductive bonding layers 190. The first spacer layers 280 laterally cover the first conductive connectors 150 and portions of the conductive bonding layers 190. For example, first spacer layers 281 may further cover the portions of the conductive bonding layers 190 closed to the first conductive connectors 151. The second spacer layers 282 laterally cover the second conductive connectors 152 and portions of the conductive bonding layers 190. For example, the second spacer layers 282 may further cover portions of the conductive bonding layers 190 closed to the second conductive connectors 152.

In an embodiment, the material and/or formation methods of the first spacer layers 281 and/or the second spacer layers 282 are the same or similar to the material and/or formation methods of the aforementioned spacer layers 180 (as shown in FIGS. 1D and/or 1E). The first spacer layers 281 and the second spacer layers 282 are physically separated from each other.

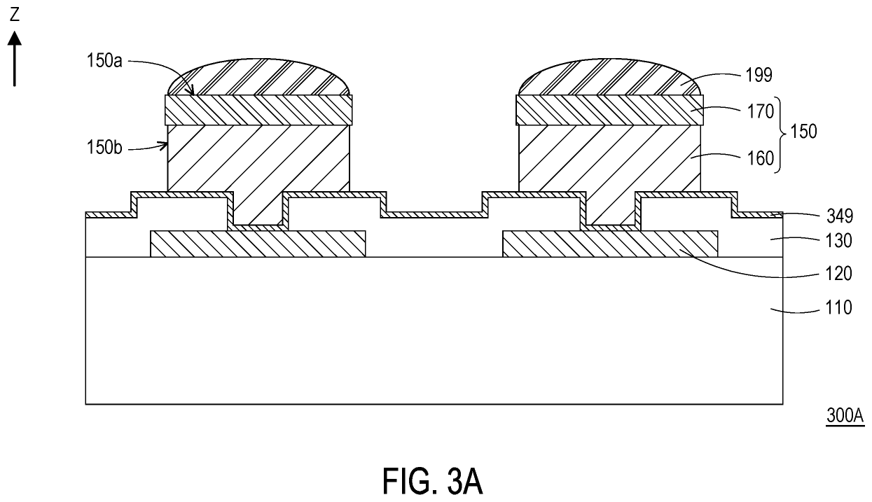

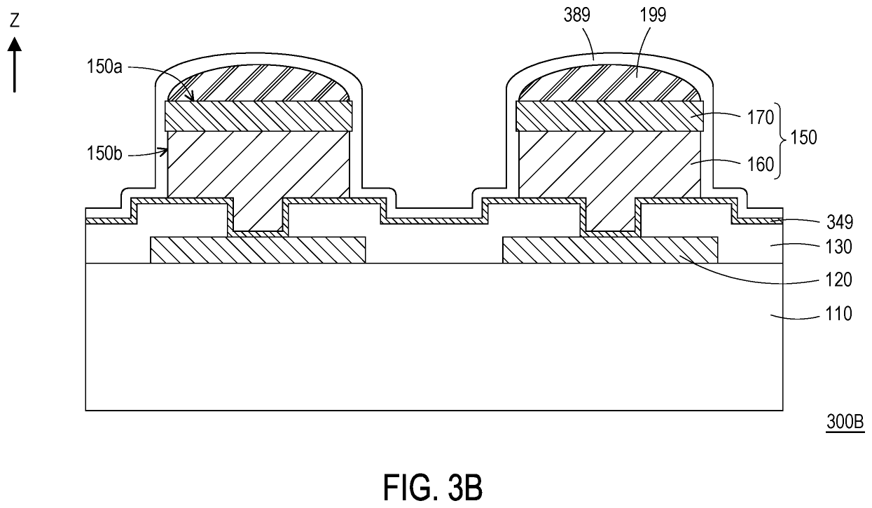

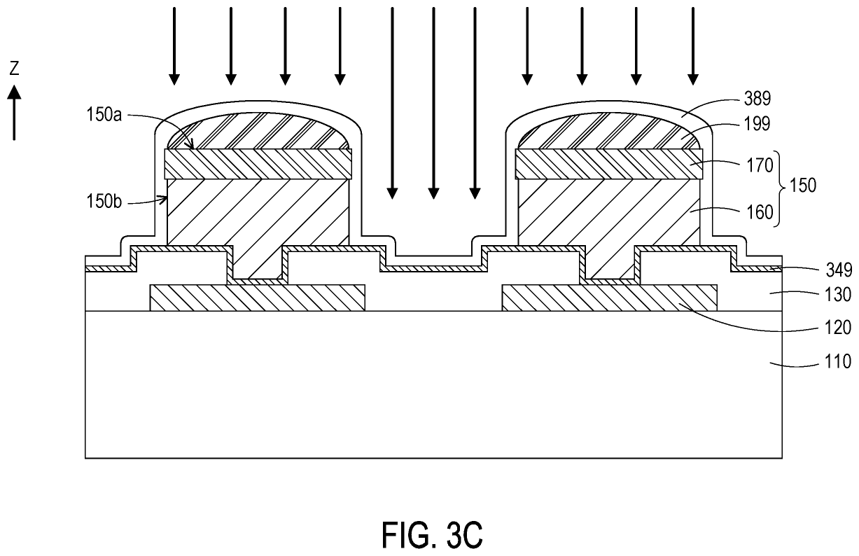

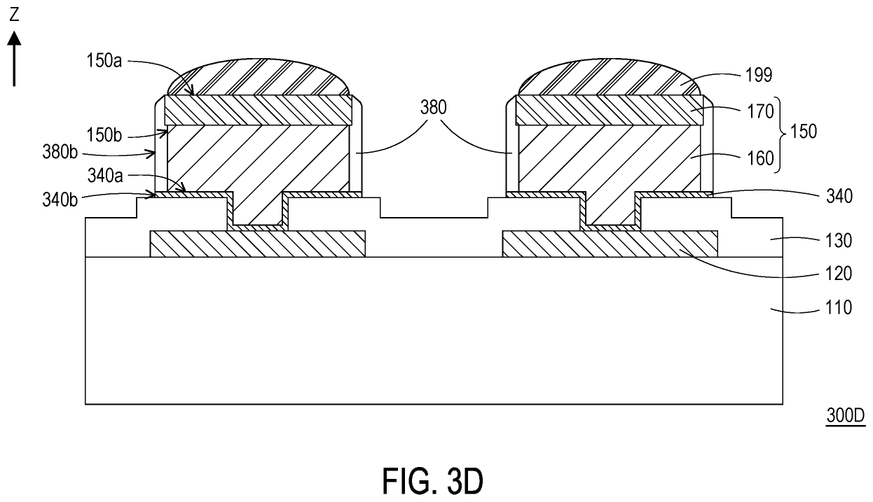

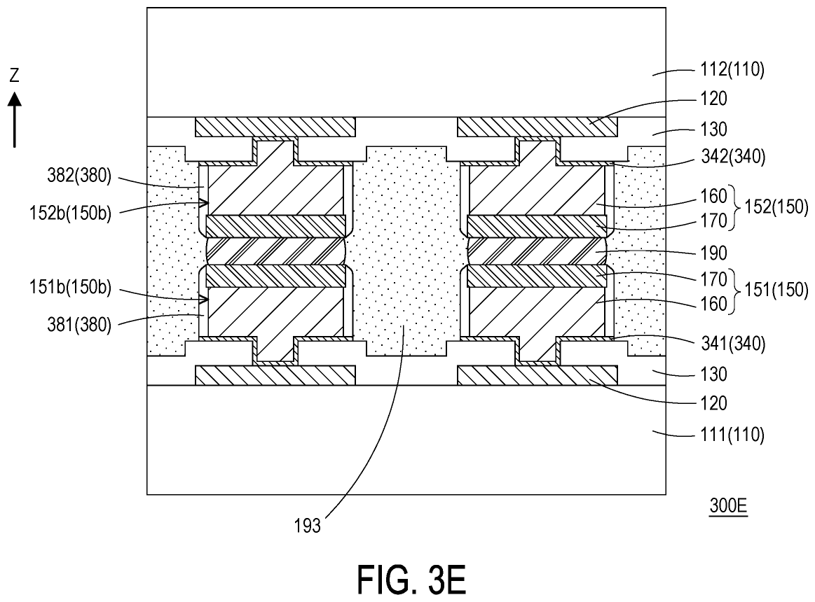

FIGS. 3A-3E illustrate various cross-sectional views of some embodiments of a method of forming an electronic device.

As shown in cross-sectional view of FIG. 3A, a structure 300A including a substrate 110, a conductive layer 349 disposed on the substrate 110, and conductive connectors 150 disposed on the conductive layer 349 is provided. The structure 300A may be referred as an electronic device. The conductive layer 349 may be formed by a deposition process (e.g., physical vapor deposition (PVD), chemical vapor deposition (CVD), atomic layer deposition (ALD), or the like), but the disclosure is not limited thereto. In an embodiment, the conductive layer 349 is a non-patterned layer. At least two of the conductive connectors 150 may be electrically connected to each other by the conductive layer 349.

The conductive layer 349 may be referred as a conductive seed layer, a conductive glue layer, or a conductive barrier layer. For example, the conductive layer 349 may reduce the possibility of the conductive connectors 150 being peeled off from the contact pads 120 and/or the insulating layer 130. For example, the conductive layer 349 may reduce the possibility of an element (e.g., Cu) in the conductive connectors 150 diffusing to another layer.

A material of the conductive layer 349 may include titanium nitride (TiN), tantalum nitride (TaN), titanium tantalum nitride (TiTaN), titanium aluminum nitride (TiAlN), titanium carbide (TiC), titanium aluminum carbide (TiAlC), aluminum doped titanium silicon carbide (TiSiAlC), tantalum aluminum carbide (TaAlC), aluminum doped tantalum silicon carbide (TaSiAlC), tungsten (W), nickel (Ni), cobalt (Co), tungsten carbonitride (WCN), or other suitable material.

As shown in cross-sectional view of FIG. 3B, a structure 300B including spacer materials 389 is provided. The spacer material 389 is formed over the conductive connectors 150 to cover the conductive connectors 150, the conductive connectors 150 and the conductive bonding material layers 199.

As shown in FIG. 3B, the spacer material 389 may conformally cover the upper surface of the structure as shown in FIG. 3A. That is, the portions of the spacer material 389 which cover the side surfaces of the conductive connectors 150 have a larger or largest dimension in the thickness direction Z of the structure 300B.

In an embodiment, a material and/or formation method of the spacer material 389 is the same or similar to the material and/or formation method of the aforementioned spacer material 189 (as shown in FIG. 1B).

Referring to FIG. 3C and FIG. 3D, a removal process is performed. The removal process may be similar to the aforementioned removal process corresponding to FIG. 1C and FIG. 1D.

The removal process may include an anisotropic dry etching process for removing a portion of the spacer material 389 and an etching process for removing a portion of the conductive layer 349. For example, after performing the above-mentioned anisotropic dry etching process, the portion of the conductive layer 349 exposed by the remained spacer material 389 (which may be the same or similar to spacer layers 380 as shown in FIG. 3D) may be removed by the subsequent etching process for forming a patterned conductive layer (e.g., patterned conductive layers 340 as shown in FIG. 3D). The patterned conductive layer 340 may have a slight undercut or side etching.

In an embodiment, after performing the above-mentioned removal process for removing the portion of the conductive layer 349, as shown in FIG. 3D, certain two of conductive connectors 150 are electrically separated to each other.

As shown in cross-sectional view of FIG. 3D, a structure 300D including spacer layers 380 is formed. The structure as shown in FIG. 3D may be referred as an electronic device.

The structure 300D may include a substrate 110, patterned conductive layers 340, conductive connectors 150, conductive bonding material layers 199, and spacer layers 380. The patterned conductive layers 340 are disposed on the substrate 110. The conductive connectors 150 are disposed on the patterned conductive layers 340. The conductive bonding material layers 199 are disposed on the conductive connectors 150. The spacer layers 380 laterally cover the conductive connectors 150. The contact pads 120, the insulating layer 130, and the patterned conductive layers 340 may be structurally considered as a part of the substrate.

The structure 300D may be referred as including a cylindrical connector having a solid cylindrical conductive core (e.g., the conductive connector 150) and an insulating layer sheath (e.g., spacer layer 380) laterally surrounding the conductive core.

In an embodiment, a maximum dimension of the spacer layers 380 is along a thickness direction Z of the structure 300D. The film thickness of portions of the spacer layers 380 corresponding to the first conductive portions 160 are larger than the film thickness of other portions of the spacer layers 380 corresponding to the second conductive portions 170.

In an embodiment, the patterned conductive layers 340 are disposed between the spacer layers 380 and the substrate 110 (or, a layer disposed on the substrate 110). As such, the possibility of the patterned conductive layers 340 being peeled off from the substrate 110 (or, a layer disposed on the substrate 110) may be reduced.

In an embodiment, the spacer layers 380 expose portions of the patterned conductive layers 340 essentially. For example, the spacer layers 380 are in contact with portions of the top surfaces 340a of the patterned conductive layers 340 and are not in contact with the side surfaces 340b of the patterned conductive layers 340.

In an embodiment, the side surfaces 380b of the spacer layers 380 are substantially aligned with the side surfaces 340b of the patterned conductive layers 340. The side surfaces 380b of the spacer layers 380 and the side surfaces 340b of the patterned conductive layers 340 are coplanar essentially.

In an embodiment, the portions (e.g., ring-shaped portions) of top surfaces 150a which are proximity to the side surfaces 150b are exposed. That is, the conductive bonding material layers 199 and the spacer layers 380 do not completely cover the top surfaces 150a of the conductive connectors 150.

In an embodiment, the conductive bonding material layers 199 are not in contact with the patterned conductive layers 340 and the side surfaces 150b of the conductive connectors 150 essentially.

As shown in cross-sectional view of FIG. 3E, a structure 300E including a conductive bonding layer 190 is formed. The structure 300E as shown in FIG. 3E may be referred as a bonded electronic device (e.g., an example type of an electronic device). For example, the structure 300D as shown in FIG. 3D is bonded to another structure which is the same or similar to the structure 300D by a corresponding bonding process, and the conductive bonding material layers 199 (as shown in FIG. 3D) may form a conductive bonding layer 190 through the aforementioned bonding process.

The structure (may be referred as a bonded electronic device) 300E may include a first substrate 111, first patterned conductive layers 341, first conductive connectors 151, first spacer layers 381, a second substrate 112, second patterned conductive layers 342, second conductive connectors 152, second spacer layers 382, and conductive bonding layers 190. The first patterned conductive layers 341 are disposed on (above in the drawing) the substrate 111. The first conductive connectors 151 are disposed on (above in the drawing) the first patterned conductive layers 341. The first spacer layers 381 laterally cover the first conductive connectors 151. The second patterned conductive layers 342 are disposed on (below in the drawing) the second substrate 112. The second conductive connectors 152 are disposed on (below in the drawing) the second patterned conductive layers 342. The second spacer layers 382 laterally cover the second conductive connectors 152. The conductive bonding layers 190 are disposed between the first conductive connectors 151 and the second conductive connectors 152 and are electrically connected thereof.

In an embodiment, the material and/or formation methods of the first spacer layers 381 and/or the second spacer layers 382 are the same or similar to the material and/or formation methods of the aforementioned spacer layers 180 (as shown in FIGS. 1D and/or 1E). The first spacer layers 381 and the second spacer layers 382 are physically separated from each other.

In an embodiment, the bonded electronic device 300E further include a filling material 193. The filling material 193 is formed between the first substrate 111 and the second substrate 112. The first spacer layers 381 are disposed between the first conductive connectors 151 and the filling material 193; and/or, the second spacer layers 382 are disposed between the second conductive connectors 152 and the filling material 193. The filling material 193 is not in contact with the side surfaces 151b of the first conductive connectors 151 and the side surfaces 152b of the second conductive connectors 152 essentially.

In an embodiment, the filling material 193 is contact with portions of top surfaces 150a of the conductive connectors 150. For example, the filling material 193 is contact with the portions (e.g., ring-shaped portions) of top surfaces 150a which are proximity to the side surfaces 150b.

In an embodiment, the filling material 193 is in contact with portions of the first patterned conductive layers 341 and/or portions of the second patterned conductive layers 342. For example, the filling material 193 is in contact with side surfaces of the first patterned conductive layers 341 and/or side surfaces of the second patterned conductive layers 342.

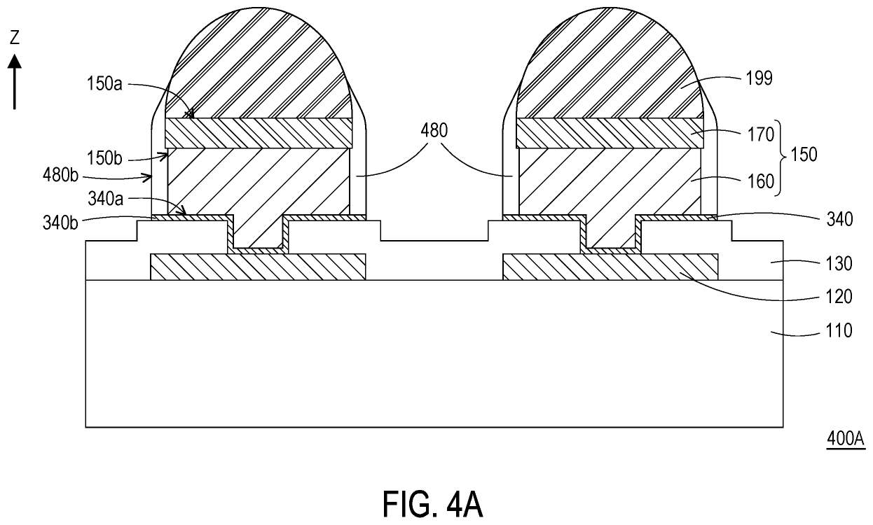

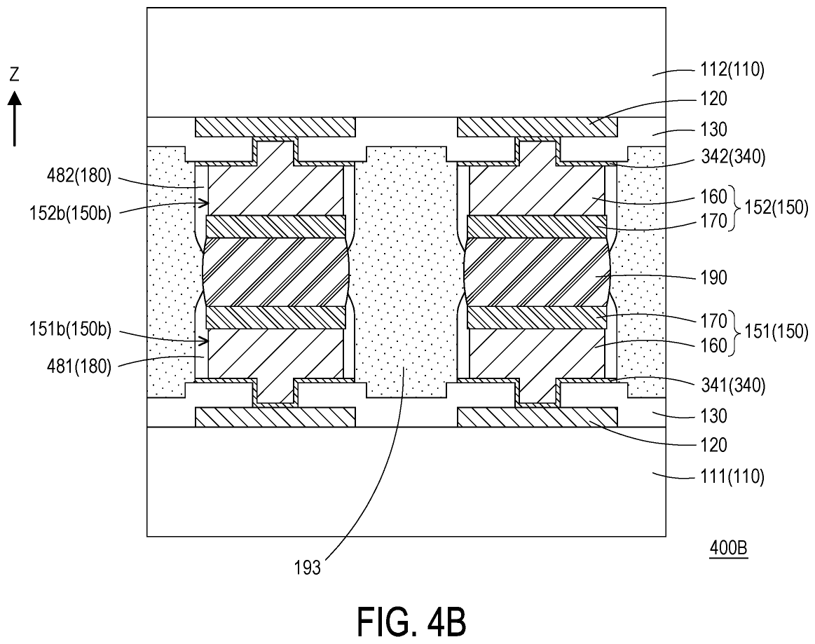

FIGS. 4A-4B illustrate various cross-sectional views of some embodiments of a method of forming an electronic device. In some embodiments, FIGS. 4A-4B may illustrate an exemplary method of forming an electronic device after the structure as shown in FIG. 3B.

As shown in cross-sectional view of FIG. 4A, a structure 400A including spacer layers 480 is formed. The structure 400A as shown in FIG. 4A may be referred as an electronic device.

The spacer layers 480 and the patterned conductive layers 340 may be formed by a removal process the same or similar to the process as described or shown in FIG. 3C.

The structure 400A may include the substrate 110, and conductive connectors 150, conductive bonding material layers 199, and spacer layers 480. The spacer layers 480 laterally cover the conductive connectors 150, and further cover portions of the conductive bonding material layers 199. The side surfaces 480b of the spacer layers 480 and the side surfaces 340b of the patterned conductive layers 340 may be coplanar essentially.

The structure 400A may be referred as including a cylindrical connector having a solid cylindrical conductive core (e.g., the conductive connector 150) and an insulating layer sheath (e.g., spacer layer 480) laterally surrounding the conductive core.

In an embodiment, a maximum dimension of the spacer layers 480 is along a thickness direction Z of the structure 400A. The film thickness of portions of the spacer layers 480 corresponding to the first conductive portions 160 are larger than the film thickness of other portions of the spacer layers 480 corresponding to the second conductive portions 170.

As shown in cross-sectional view of FIG. 4B, a structure 400B including a conductive bonding layer 190 is formed. The structure 400B as shown in FIG. 4B may be referred as a bonded electronic device (e.g., an example type of an electronic device). For example, the structure 400A as shown in FIG. 4A is bonded to another structure which is the same or similar to the structure 400A by a corresponding bonding process.

The structure (may be referred as a bonded electronic device) 400B may include a first substrate 111, first patterned conductive layers 341, first conductive connectors 151, first spacer layers 481, a second substrate 112, second patterned conductive layers 342, second conductive connectors 152, second spacer layers 482, and conductive bonding layers 190. The first spacer layers 481 laterally cover the first conductive connectors 152 and portions of the conductive bonding layers 190. For example, the first spacer layers 481 may further cover portions of the conductive bonding layers 190 closed to the first conductive connectors 151. The second spacer layers 482 laterally cover the second conductive connectors 152 and portions of the conductive bonding layers 190. For example, the second spacer layers 482 may further cover portions of the conductive bonding layers 190 closed to the second conductive connectors 152.

In an embodiment, the material and/or formation methods of the first spacer layers 481 and/or the second spacer layers 482 are the same or similar to the material and/or formation methods of the aforementioned spacer layers 180 (as shown in FIGS. 1D and/or 1E). The first spacer layers 481 and the second spacer layers 482 are physically separated from each other.

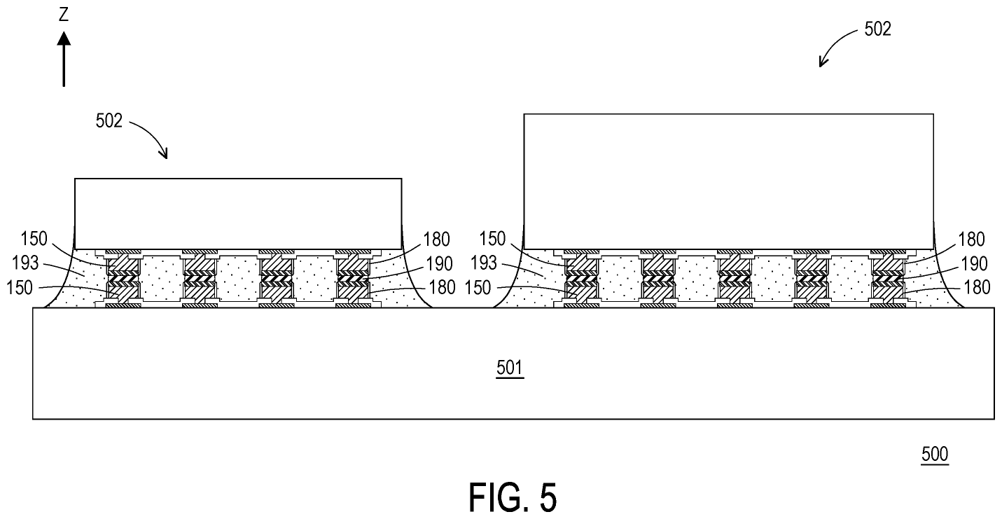

FIG. 5 illustrates an exemplary cross-sectional view of an electronic device.

The structure 500 as shown in FIG. 5 may be referred as a bonded electronic device (e.g., an example type of an electronic device).

For example, the bonded electronic device 500 may include a first electronic device 501 and at least one second electronic device 502 disposed and bonded thereon. It is worth noting that, the first electronic device 501 and/or the second electronic device 502 as shown in FIG. 5 are exemplary illustrated the same or similar to the structure 100D as shown in FIG. 1D in a clear and/or simple manner, but the disclosure is not limited thereto. The first electronic device 501 and/or the second electronic device 502 may be the same or similar to the structures 100D, 200A, 300D, 400A as shown in FIG. 1D, 2A, 3D, or 4A. Additionally, the conductive bonding layer 190 through the aforementioned bonding process. Moreover, two second electronic devices 502 are exemplary illustrated in FIG. 5, but the disclosure is not limited thereto. A filling material 193 may be formed between the first electronic device 501 and the second electronic device 502. The bonded electronic device 500 may be referred as a three-dimensional integrated circuit (3DIC) or a 2.5D integrated circuit (2.5D IC).

If there are more than one second electronic devices 502 in the bonded electronic device 500, the sizes, functions, and/or applications of two of the second electronic devices 502 may be the same or different form each other. The first electronic device 501 and the second electronic device 502 may be heterogeneous dies. For example, one of first electronic device 501 and the second electronic device 502 may be a dynamic random access memory (DRAM) die, a static random access memory (SRAM) die or a high bandwidth memory (HBM) die; and, the other one of the first electronic device 501 and the second electronic device 502 may be an application-specific integrated circuit (ASIC) die, an application processor (AP) die, a system on chip (SoC) die or a high performance computing (HPC) die.

In an embodiment, one of first electronic device 501 and the second electronic device 502 is an interposer, and the other one of the first electronic device 501 and the second electronic device 502 is a die.

In an embodiment, the bonded electronic device 500 is a CoW (Chip-on-Wafer) structure. For example, the first electronic device 501 is a functional wafer having at least on good die area, and the second electronic device 502 is a die disposed on the good die area.

The bonded electronic device 500 may be disposed on and electrically connected to a substrate (e.g., a circuit board), and may be referred as a CoWoS (Chip on Wafer on Substrate) structure.

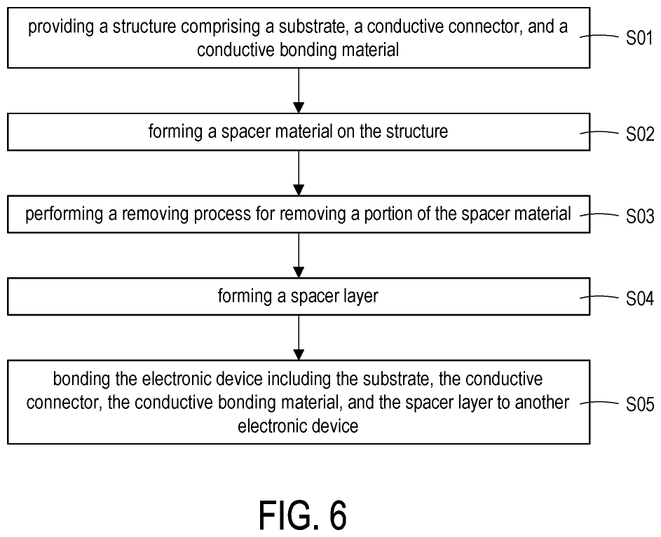

FIG. 6 illustrates a flow diagram of some embodiments of a method of forming an electronic device.

At act S01, an electronic device including a substrate, a conductive connector disposed thereon, and a conductive bonding material disposed thereon is provided. FIGS. 1A and/or 3A illustrates cross-sectional view corresponding to various embodiments of act S01.

At act S02, a spacer material is formed on the electronic device including the substrate, the conductive connector, and the conductive bonding material. FIGS. 1B and/or 3B illustrates cross-sectional view corresponding to various embodiments of act S02.

At act S03, a removal process is performed on the spacer material for at least removing a portion of the spacer material. FIGS. 1C and/or 3C illustrates cross-sectional view corresponding to various embodiments of act S03.

At act S04, after performing the removal process, the remained spacer material forms a spacer layer laterally covering the conductive connector. As such, an electronic device including the substrate, the conductive connector, the conductive bonding material, and the spacer layer is obtained. FIGS. 1D, 2A, 3D and/or 4A illustrates cross-sectional view corresponding to various embodiments of act S04.

At optional act S05, the electronic device including the substrate, the conductive connector, the conductive bonding material, and the spacer layer may be bonded to another electronic device which is the same or similar thereto. FIGS. 1E, 2B, 3E and/or 4B illustrates cross-sectional view corresponding to various embodiments of act S05.

Accordingly, in some embodiments, the present disclosure relates to an electronic device including a spacer layer laterally covering a conductive connector may have a better electrical performance and/or yield.

In accordance with some embodiments of the present disclosure, an electronic device includes a substrate, a conductive connector, a conductive bonding material, and a spacer layer. The conductive connector is disposed on the substrate. The conductive bonding material is disposed on the conductive connector. The spacer layer laterally covers the conductive connector. In an embodiment, a melting point of the conductive bonding material is lower than a melting point of the conductive connector, and the melting point of the conductive bonding material is lower than a melting point of the spacer layer. In an embodiment, a material of the spacer layer is an inorganic material. In an embodiment, a maximum dimension of the spacer layer is along a thickness direction of the electronic device. In an embodiment, the spacer layer further covers a portion of the conductive bonding material. In an embodiment, the substrate includes a patterned conductive layer. The spacer layer is in contact with a portion of a top surface of the patterned conductive layer. In an embodiment, the spacer layer is not in contact with a side surface of the patterned conductive layer. In an embodiment, a side surface of the spacer layer is substantially aligned with a side surface of the patterned conductive layer. In an embodiment, the electronic device further includes a filling material. The filling material is disposed on the substrate. The spacer layer is disposed between the conductive connector and the filling material. In an embodiment, the substrate includes a patterned conductive layer. The spacer layer directly is in contact with a portion of a top surface of the patterned conductive layer. The filling material is in contact with a side surface of the patterned conductive layer.

In accordance with some embodiments of the present disclosure, a semiconductor structure includes a first electronic device, a second electronic device, and a conductive bonding layer. The first electronic device includes a first substrate, a first conductive connector, and a first spacer layer. The first conductive connector is disposed on the first substrate. The first spacer layer laterally covers the first conductive connector. The second electronic device includes a second substrate, a second conductive connector, and a second spacer layer. The second conductive connector is disposed on the second substrate. The second spacer layer laterally covers the second conductive connector. The conductive bonding layer is disposed between the first conductive connector and the second conductive connector. In an embodiment, the bonded electronic device further includes a filling material. The filling material is disposed between the first substrate and the second substrate. The first spacer layer and the second spacer layer are laterally encapsulated by the filling material. In an embodiment, a portion of the conductive bonding layer is covered by the first spacer layer and/or the second spacer layer.

In accordance with some embodiments of the present disclosure, a method includes: providing an electronic device comprising a substrate, a conductive connector, and a conductive bonding material, wherein the conductive connector is disposed on the substrate, and the conductive bonding material is disposed on the conductive connector; forming a spacer material on the electronic device; and performing a removal process for removing a portion of the spacer material to form a spacer layer laterally covering the conductive connector. In an embodiment, the spacer material conformally covers an upper surface of the electronic device before removing the portion of the spacer material to form the spacer layer. In an embodiment, the portion of the spacer material is removed by a process without using a mask. In an embodiment, the portion of the spacer material is removed by an anisotropic dry etching process. In an embodiment, the method further includes: performing a heating process to melt the conductive bonding material after forming the spacer layer. In an embodiment, a cohesion of a molten conductive bonding material is greater than an adhesion between the molten conductive bonding material and the spacer layer. In an embodiment, an adhesion between a molten conductive bonding material and the conductive connector is greater than an adhesion between the molten conductive bonding material and the spacer layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic device, comprising:
a substrate;
a conductive connector, disposed on the substrate;
a conductive bonding material, disposed on the conductive connector; and
a spacer layer, laterally covering the conductive connector.

2. The electronic device of claim 1, wherein a melting point of the conductive bonding material is lower than a melting point of the conductive connector, and the melting point of the conductive bonding material is lower than a melting point of the spacer layer.

3. The electronic device of claim 1, wherein a material of the spacer layer is an inorganic material.

4. The electronic device of claim 1, wherein a maximum dimension of the spacer layer is along a thickness direction of the electronic device.

5. The electronic device of claim 1, wherein the spacer layer further covers a portion of the conductive bonding material.

6. The electronic device of claim 1, wherein the substrate comprises:
a patterned conductive layer, wherein the spacer layer is in contact with a portion of a top surface of the patterned conductive layer.

7. The electronic device of claim 6, wherein the spacer layer is not in contact with a side surface of the patterned conductive layer.

8. The electronic device of claim 6, wherein a side surface of the spacer layer is substantially aligned with a side surface of the patterned conductive layer.

9. The electronic device of claim 1, further comprising:
a filling material, disposed on the substrate, wherein the spacer layer is disposed between the conductive connector and the filling material.

10. The electronic device of claim 9, wherein the substrate comprises:
a patterned conductive layer, wherein the spacer layer is in contact with a portion of a top surface of the patterned conductive layer, and the filling material is in contact with a side surface of the patterned conductive layer.

11. A semiconductor structure, comprising:
a first electronic device, comprising:
a first substrate;
a first conductive connector, disposed on the first substrate;
a first spacer layer, laterally covering the first conductive connector;
a second electronic device, comprising:
a second substrate;
a second conductive connector, disposed on the second substrate;
a second spacer layer, laterally covering the second conductive connector; and
a conductive bonding layer, disposed between the first conductive connector and the second conductive connector.

12. The semiconductor structure of claim 11, further comprising:
a filling material, disposed between the first substrate and the second substrate, wherein the first spacer layer and the second spacer layer are laterally encapsulated by the filling material.

13. The semiconductor structure of claim 11, wherein a portion of the conductive bonding layer is covered by the first spacer layer and/or the second spacer layer.

14. A method, comprising:
providing an electronic device comprising a substrate, a conductive connector, and a conductive bonding material, wherein the conductive connector is disposed on the substrate, and the conductive bonding material is disposed on the conductive connector;
forming a spacer material on the electronic device; and
removing a portion of the spacer material to form a spacer layer laterally covering the conductive connector.

15. The method of claim 14, wherein the spacer material conformally covers an upper surface of the electronic device before removing the portion of the spacer material to form the spacer layer.

16. The method of claim 14, wherein the portion of the spacer material is removed by a process without using a mask.

17. The method of claim 14, wherein the portion of the spacer material is removed by an anisotropic dry etching process.

18. The method of claim 14, further comprising:
performing a heating process to melt the conductive bonding material after forming the spacer layer.

19. The method of claim 18, wherein a cohesion of a molten conductive bonding material is greater than an adhesion between the molten conductive bonding material and the spacer layer.

20. The method of claim 18, wherein an adhesion between a molten conductive bonding material and the conductive connector is greater than an adhesion between the molten conductive bonding material and the spacer layer.
